(19) United States
(12) Patent Application Publication
(10) Pub. No.: US 2014/0368997 A1
(43) Pub. Date: Dec. 18, 2014

(54) SERVER CABINET

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: JUN-HUI WANG, Shenzhen (CN); XIAO-GANG YIN, Shenzhen (CN)

(21) Appl. No.: 14/304,994

(22) Filed: Jun. 16, 2014

(30) Foreign Application Priority Data
Jun. 18, 2013 (CN) 2013102404931

(51) Int. Cl. H05K 7/14

(52) U.S. Cl. CPC H05K 7/1489; H05K 7/1487
USPC 361/679.58

(57) ABSTRACT

A server cabinet with a safety catch preventing free disengagement of a pulled-out server includes a rack, a server, and a latching member. The rack includes a pole. The server includes a side plate. The side plate defines a through hole and an opening. The latching member includes a mounting plate, a latch extending from the mounting plate, and a button extending from the mounting plate. A first end of the mounting plate is fastened to an inner surface of the side plate. The latch extends through the through hole for exposing out of the server. The button is received in the opening. When the server is pulled out of the rack, the latch is blocked by the pole, the button must be pressed to deform the mounting plate to allow the latch to disengage from the pole.

### FIELD

The present disclosure relates to server cabinet construction.

### BACKGROUND

A server cabinet comprises a rack and a plurality of servers mounted in the rack.

When the servers are pulled out of the rack, the servers can drop from the rack.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a server cabinet, wherein the server cabinet comprises two latching members.

FIG. 2 is an exploded, isometric view of the server cabinet of FIG.1.

FIG. 3 is an enlarged view of circled portion III of FIG. 2.

FIG. 4 is an enlarged view of one of the latching members of FIG. 1.

FIG. 5 is an enlarged view of circled portion V of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

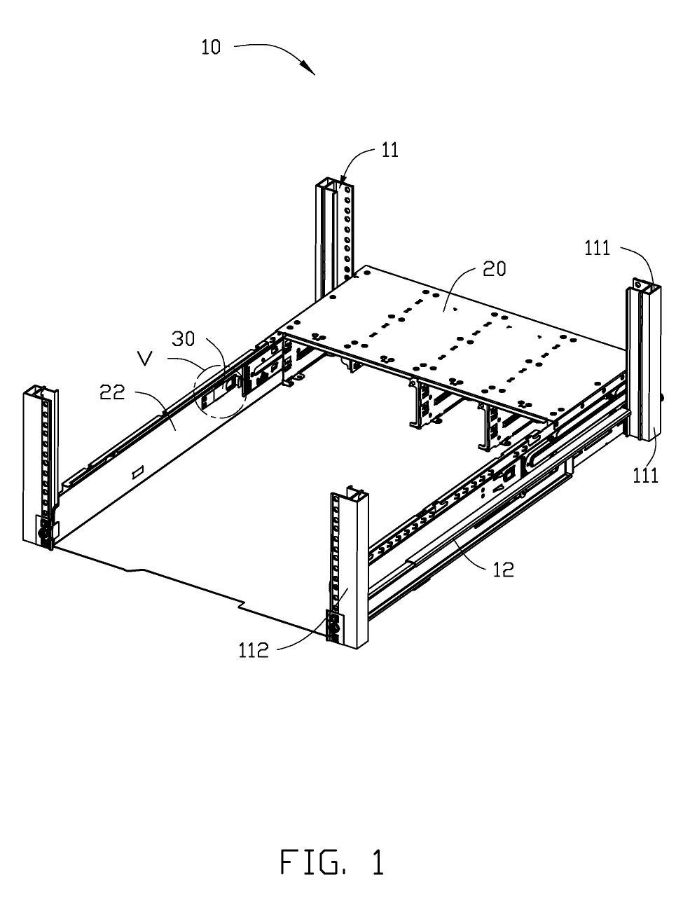

FIG. 1 shows an exemplary embodiment of a server cabinet 10. The server cabinet 10 comprises a rack 11, a server 20, and two latching members 30.

The rack 11 comprises two first poles 111 at a front end of the rack 11, two second poles 112 at a rear end of the rack 11, and two slide rails 12 located at opposite sides of the rack 11. Each slide rail 12 is connected between the corresponding first pole 111 and the corresponding second pole 112.

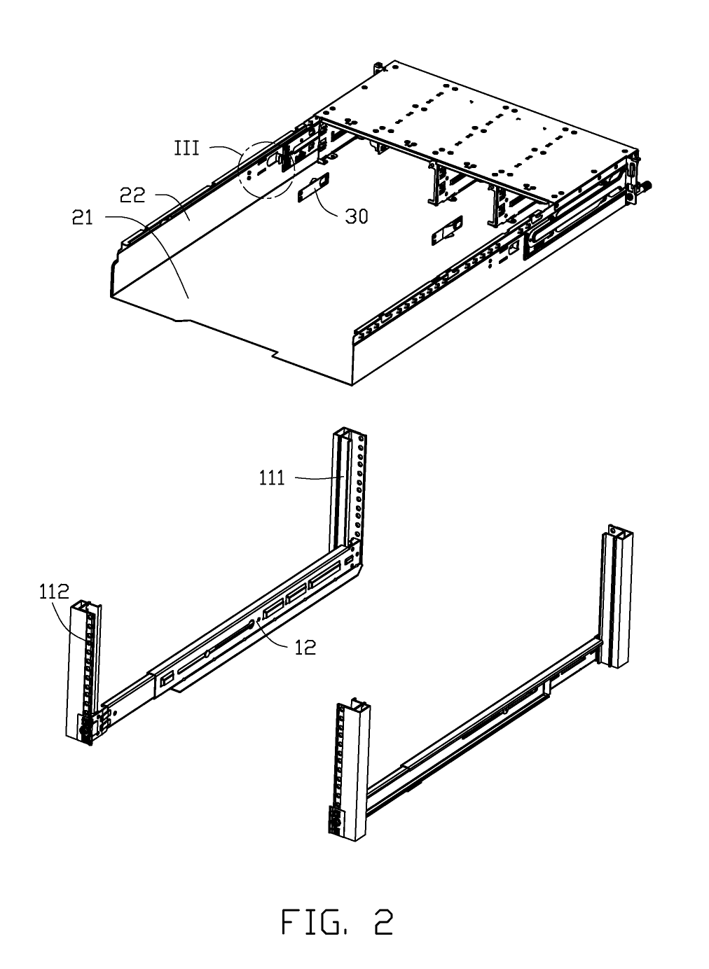

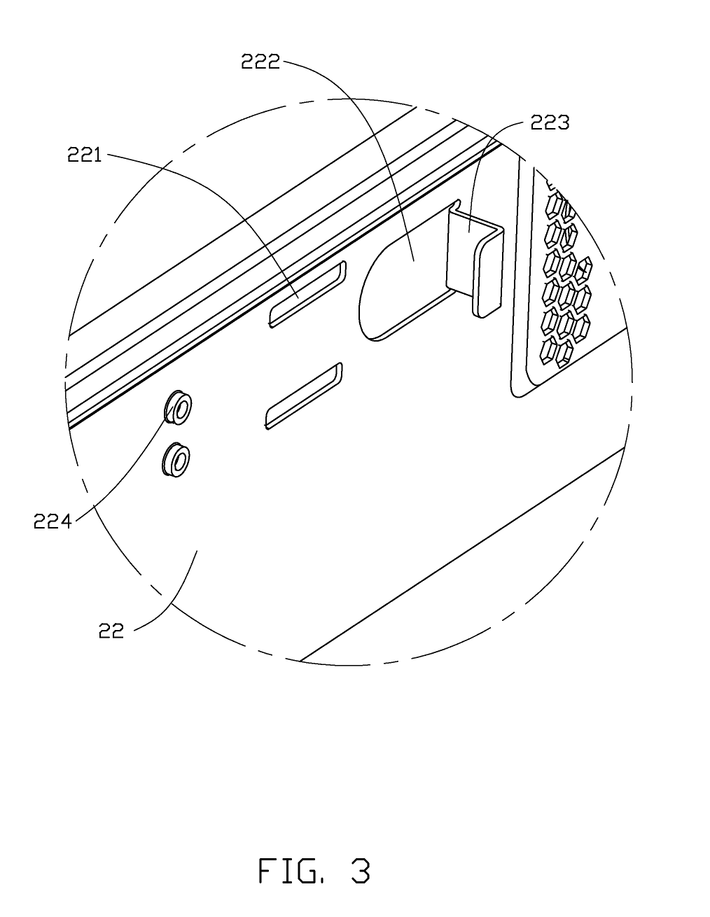

FIGS. 2 and 3 show the server 20 comprising a bottom plate 21 and two side plates 22 extending up from opposite sides of the bottom plate 21.

Each side plate 22 defines two parallel through holes 221 and an opening 222 in front of the through holes 221. An L-shaped limiting portion 223 extends from an inner surface of the side plate 22, and is located at a front end of the opening 222. Two pins 224 extend from the inner surface of the side plate 22, being located behind the through holes 221.

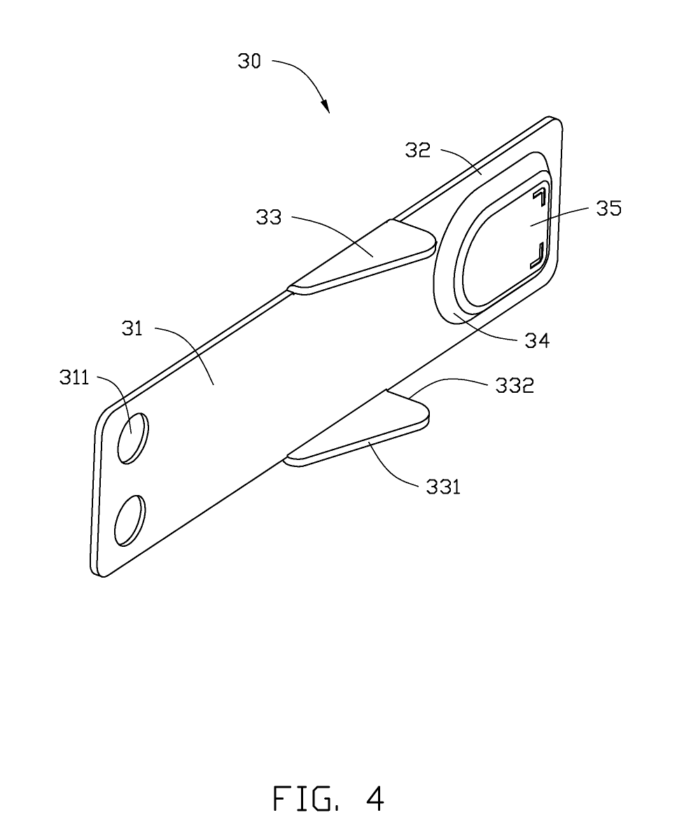

FIG. 4 shows each latching member 30 comprises a mounting plate 31. Two mounting holes 311 are defined in a first end of the mounting plate 31. A button 34 extends from a second end 32 of the mounting plate 31. An anti-skip pad 35 is attached to the button 34, for operating the button 34. Two latches 33 extend from opposite sides of the mounting plate 31. Each latch 33 comprises a slanted surface 331 facing the mounting holes 311 and a stop surface 332 facing the button 34. The stop surface 332 is perpendicular to the mounting plate 31.

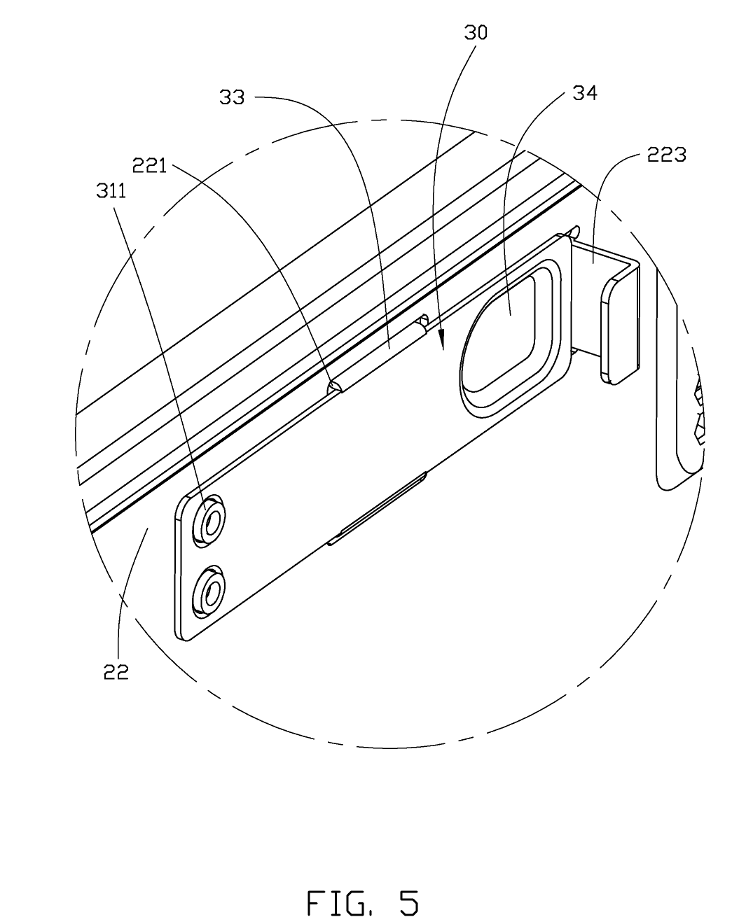

FIGS. 1 and 5 show assembly, in which the pins 224 extend through the mounting holes 311 and are riveted to the latching members 30. The latches 33 of the latching members 30 extend through the through holes 221 of the side plates 22 and are exposed out of the server 20. The buttons 34 of the latching members 30 are received in the openings 222 of the side plates 22.

To mount the server 20 to the rack 11, the server 20 is placed in front of the rack 11 and the server 20 is pushed into the rack 11 and slid along the slide rails 12. When the slanted surfaces 331 of the latching members 30 abut against the first poles 111, the second ends 32 of the mounting plates 31 are deformed, to allow the latches 33 to be received in the server 20 through the through holes 221. After the latches 33 pass through the first poles 111, the second ends 32 of the mounting plates 31 restore. The server 20 is pushed toward the second poles 112, then the server 20 can be mounted among the first poles 111 and the second poles 112.

To pull the server 20 out of the rack 11, the server 20 is pulled forward. When the stop surfaces 332 of the latching members 30 are blocked by the first poles 111, the server 20 is prevented from being moving further. Then the buttons 34 are pressed, to allow the second ends 32 of the mounting plates 31 to deform. The latches 33 are received in the server 20. Thus, the server 20 can be pulled out of the rack 11. The limiting portions 223 prevent excessive deformation of the second ends 32 of the mounting plates 31.

When detaching the server 20 from the front end of the rack 11, the stop surfaces 332 of the latching members 30 are blocked by the first poles 111, which reminds users to catch the server 20 after the buttons 34 are pressed and the latches 33 pass through the first poles 111, to prevent the server 20 from dropping from the rack 11.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A server cabinet, comprising:
a rack comprising a pole;
a server comprising a side plate, the side plate defining a through hole and an opening; and
a latching member comprising a mounting plate, a latch extending from the mounting plate, and a button extending from the mounting plate, a first end of the mounting plate fastened to an inner surface of the side plate, the latch extending through the through hole for being exposed out of the server, the button being received in the opening;
wherein when the server is pulled out of the rack in a direction toward the pole, the latch is blocked by the pole to prevent the server to further move; when the button is pressed to deform the mounting plate, the latch is allowed to pass the pole to disengage from the pole.

2. The server cabinet of claim 1, wherein the latch comprises a slanted surface facing the first end of the mounting plate and a stop surface facing a second end of the mounting plate opposite to the first end, the stop surface is perpendicular to the mounting plate.

3. The server cabinet of claim 2, wherein the button extends from the second end of the mounting plate, an L-shaped limiting portion extends from the inner surface of the side plate and is near the opening.

4. The server cabinet of claim 1, wherein the latching member further comprises an anti-skip pad attached to the button.

5. A server, comprising:
a side plate defining a through hole and an opening; and
a latching member comprising a mounting plate, a latch extending from the mounting plate, and a button extending from the mounting plate, a first end of the mounting plate fastened to an inner surface of the side plate, the latch extending through the through hole for being exposed out of the server, the button being received in the opening.

6. The server of claim 5, wherein the latch comprises a slanted surface facing the first end of the mounting plate and a stop surface facing a second end of the mounting plate opposite to the first end, the stop surface is perpendicular to the mounting plate.

7. The server of claim 6, wherein the button extends from the second end of the mounting plate, an L-shaped limiting portion extends from the inner surface of the side plate and is near the opening.

8. The server of claim 5, wherein the latching member further comprises an anti-skip pad attached to the button.
